(19) United States
(12) Patent Application Publication
(10) Pub. No.: US 2006/0118898 A1
(43) Pub. Date: Jun. 8, 2006

(54) Photoelectric conversion device and method of manufacturing the same

(75) Inventors: Kouichi Uchimoto, Shiga (JP); Jun Fukuda, Shiga (JP); Hideki Hakuma, Shiga (JP); Shin Sugawara, Shiga (JP); Hisao Arimune, Shiga (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/283,609

(22) Filed: Nov. 17, 2005

(30) Foreign Application Priority Data
Nov. 17, 2004 (JP) 2004-332931
Dec. 1, 2004 (JP) 2004-348403

(51) Int. Cl. H01L 31/06

(52) U.S. Cl. 257/461

(57) ABSTRACT

Disclosed is a photoelectric conversion device in which a plurality of p-type crystal semiconductor particles 4 are joined to one main surface of a conductive substrate 2. A boron concentration in a junction of a lower part of each of the p-type crystal semiconductor particles 4 with the conductive substrate 2 is higher than a boron concentration in a portion, other than the junction, of the p-type crystal semiconductor particle 4. The junction is a p+ layer having a high impurity concentration. The p+ layer allows p-type carriers to be collected, thereby making it possible to improve a BFS effect.

### BACKGROUND OF THE INVENTION

1. Field of the Invention

The present invention relates to a photoelectric conversion device used for solar photoelectric generation or the like, and more particularly, to a photoelectric conversion device using crystal semiconductor particles and a method of manufacturing the same.

2. Description of Related Art

Conventional photoelectric conversion elements using general crystal semiconductors are so configured that an n-type semiconductor region is formed on one main surface of a p-type silicon substrate to form a pn junction, and electrodes are respectively formed on the transparent electrode and the other main surface of the p-type silicon substrate.

In recent years, an output of a solar cell has been strongly required to be improved. As one measure to improve the output of the solar cell, it has been desired to improve a BSF (Back Surface Field) effect. For this purpose, a p+ layer has been formed in the interface of a p-type semiconductor and an electrode on its reverse surface. Various considerations of a paste composition used for forming the p+ type layer have been made.

For example, a paste comprising 60 to 90% by weight of a solid content and 10 to 40% of an organic vehicle in terms of a mixture ratio with the whole thereof, the solid content comprising 85 to 98.5% by weight of silver powder, 0.5 to 10% by weight of aluminum powder, and 1 to 10% by weight of a glass flit in terms of a mixture ratio with the whole thereof, has been proposed (see Japanese Unexamined Patent Publication (KOKAI) No. 08-148447).

Furthermore, a paste comprising Al powder, 0.3 to 50 parts by weight of Si per 100 parts by weight of the Al powder, an organic solvent, and an organic binder added as required has been proposed (see Japanese Unexamined Patent Publication (KOKAI) No. 2001-313402).

Furthermore, a paste comprising at least one type selected from a group consisting of aluminum powder, an organic vehicle, a glass frit, boron powder, an inorganic boron compound, an organic boron compound has been proposed (see Japanese Unexamined Patent Publication (KOKAI) No. 2003-69056).

However, all the pastes disclosed in the foregoing documents are applied to a substrate composed of a p-type silicon semiconductor.

It has been difficult to apply the pastes to a photoelectric conversion device of a ball solar type in which crystal semiconductor particles are aligned with one another and are welded to an aluminum substrate.

In the photoelectric conversion device using the crystal semiconductor particles, therefore, it has been impossible to improve the BSF effect. Therefore, the photoelectric conversion device using the crystal semiconductor particles has been low in photoelectric conversion efficiency.

An object of the present invention is to provide a photoelectric conversion device using crystal semiconductor particles having higher photoelectric conversion efficiency.

### SUMMARY OF THE INVENTION

A photoelectric conversion device according to the present invention is characterized by comprising a conductive substrate; a plurality of p-type crystal semiconductor particles joined to one main surface of the conductive substrate; an insulator interposed between the adjacent p-type crystal semiconductor particles on the one main surface of the conductive substrate; and a n-type semiconductor layer and a translucent conductor layer that are formed on a portion, exposed from the insulator, of each of the p-type crystal semiconductor particles, and in that a boron concentration in a junction of the p-type crystal semiconductor particle with the conductive substrate is higher than a boron concentration in a portion, other than the junction, of the p-type crystal semiconductor particle.

According to the photoelectric conversion device according to the present invention, the boron concentration in the junction of a lower part of each of the p-type crystal semiconductor particles with the conductive substrate is higher than the boron concentration in the remainder of the p-type crystal semiconductor particle, so that the junction is a p+ layer. Therefore, p-type carriers (holes) can be efficiently collected from a pn junction in an upper part of the p-type crystal semiconductor particle to the p+ layer. As a result, photoelectric conversion efficiency can be improved.

The conductive substrate may be an aluminum substrate containing boron. In this case, it is preferable that the content of boron in the conductive substrate is 50 to 300 ppm.

The conductive substrate may be one having an aluminum layer containing boron formed on its surface. In this case, it is preferable that the content of boron in the aluminum layer is 50 to 300 ppm, and it is preferable that the thickness of the aluminum layer is not less than 10 μm. In this case, it is preferable that the conductive substrate is composed of aluminum, a metal having a melting point that is not less than the melting point of aluminum, or ceramics.

A method of manufacturing a photoelectric conversion device is a method comprising the steps of preparing a plurality of p-type crystal semiconductor particles as well as preparing a conductive substrate containing boron; joining each of the plurality of p-type crystal semiconductor particles onto the conductive substrate by heating and welding, to diffuse boron into its junction; first carrying out either one of the step of forming an n-type semiconductor portion except for at least the junction on a surface of each of the p-type crystal semiconductor particles and the step of covering a lower part of the n-type semiconductor portion and the conductive substrate between the adjacent p-type crystal semiconductor particles and exposing an upper part of the n-type semiconductor portion to form an insulator, and then carrying out the other step; and forming a translucent conductor layer that covers the insulator and the upper part of the n-type semiconductor portion.

According to the manufacturing method, the method has the step of joining each of the plurality of p-type crystal semiconductor particles onto the conductive substrate by heating and welding, to diffuse boron into the junction in a lower part of the p-type crystal semiconductor particle with the conductive substrate, so that a boron concentration in the junction can be made higher than a boron concentration in the remainder of the p-type crystal semiconductor particle. Therefore, the junction of the lower part of the p-type crystal semiconductor particle with the conductive substrate is a p+ layer, so that electrons can be efficiently collected to a pn junction in an upper part of the p-type crystal semiconductor particle apart from the p+ layer. As a result, a photoelectric conversion device having improved photoelectric conversion efficiency can be obtained.

The conductive substrate containing boron may be a conductive substrate having a boron compound layer formed on its surface, may be a conductive substrate containing boron, or may be a conductive substrate having a layer containing boron formed on its surface.

When the conductive substrate having the boron compound layer formed therein is used, the boron compound layer may be composed of at least one type of inorganic boron compound selected out of carbide, oxide, and chloride. Thus, a chemically stable boron compound layer can be formed. When the p-type crystal semiconductor particles are joined to the conductive substrate by heating and welding, boron can be stably diffused and doped into the junction.

The boron compound layer may be composed of at least one type of organic boron compound selected out of trimethoxyboron, triethoxyboron, tripropoxyboron, and tributoxyboron. In this case, the boron compound layer can be easily formed by applying or spraying the organic boron compound such as trimethoxyboron with the organic boron compound contained in alcohol, water, or the like.

It is preferable that the content of boron in the boron compound layer is 0.1×10⁻⁵ to 1×10⁻⁵ g/cm³.

When the conductive substrate is aluminum, heating temperature in carrying out the joining step can be set to a low temperature of 560 to 660° C. In this case, boron can be reliably doped into the p-type crystal semiconductor particles without melting aluminum by heating.

A photoelectric apparatus according to the present invention uses the photoelectric conversion device according to the present invention as power generation means and is configured so as to supply power generated by the power generation means to a load. Since the photoelectric apparatus uses the photoelectric conversion device having high photoelectric conversion efficiency is used, the power generation efficiency of the photoelectric apparatus can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing an example of an embodiment of a photoelectric conversion device according to the present invention;

FIG. 2 is a cross-sectional view showing another example of the embodiment of the photoelectric conversion device according to the present invention;

FIG. 3 is a cross-sectional view showing an example of another embodiment of the photoelectric conversion device according to the present invention;

FIG. 4 is a cross-sectional view showing the shape of a boundary surface of a junction of each of crystal semiconductor particles in a photoelectric conversion device in a comparative example;

FIGS. 5(a) to 5(e) are cross-sectional views showing various examples of a boundary surface of a junction of each of crystal semiconductor particles in the photoelectric conversion device according to the present invention; and

FIGS. 6(a) and 6(b) are diagrams showing parts of steps of manufacturing the photoelectric conversion device according to the present invention.

### DETAILED DESCRIPTION OF PREFERRED EMBODIMENTS

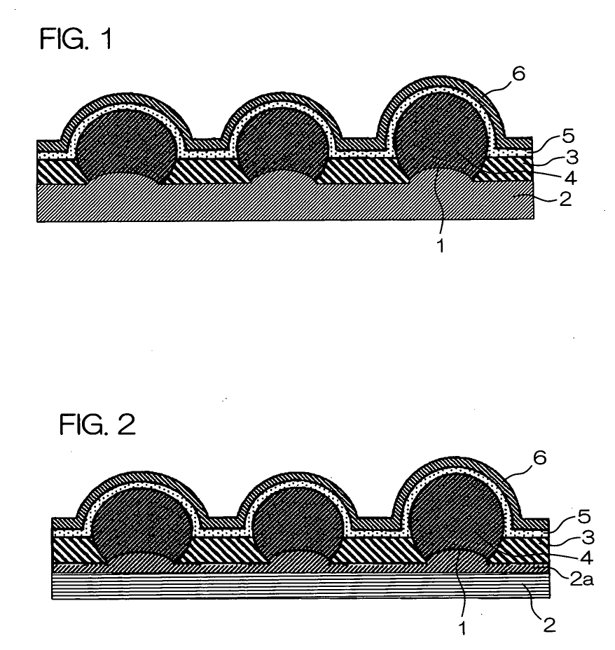

FIGS. 1 and 2 are cross-sectional views showing an example of a solar cell serving as a photoelectric conversion device according to the present invention.

Reference numeral 2 denotes a metallic conductive substrate composed of aluminum or the like, reference numeral 3 denotes a layered insulator, reference numeral 4 denotes a p-type crystal semiconductor particle mainly composed of silicon, reference numeral 5 denotes an n-type semiconductor layer, and reference numeral 6 denotes a translucent conductive layer.

The conductive substrate 2 is composed of an aluminum substrate containing boron, as shown in FIG. 1.

Alternatively, the conductive substrate 2 is composed of a composite material obtained by forming an aluminum alloy layer 2a containing born on a surface of a conductive substrate composed of aluminum or the like, as shown in FIG. 2.

In the conductive substrate 2 shown in FIG. 1, it is preferable that the content of boron in aluminum is 50 to 300 ppm. When the content of boron is more than 300 ppm, the melting temperature of aluminum containing boron is rapidly raised, so that it is difficult to melt a material for producing the conductive substrate 2. When the content of boron is less than 50 ppm, an effect produced by containing boron in the conductive substrate 2 is reduced. That is, a junction in a lower part of the p-type crystal semiconductor particle 4 does not easily become a p+ layer, so that an effect produced by having the p+ layer is reduced.

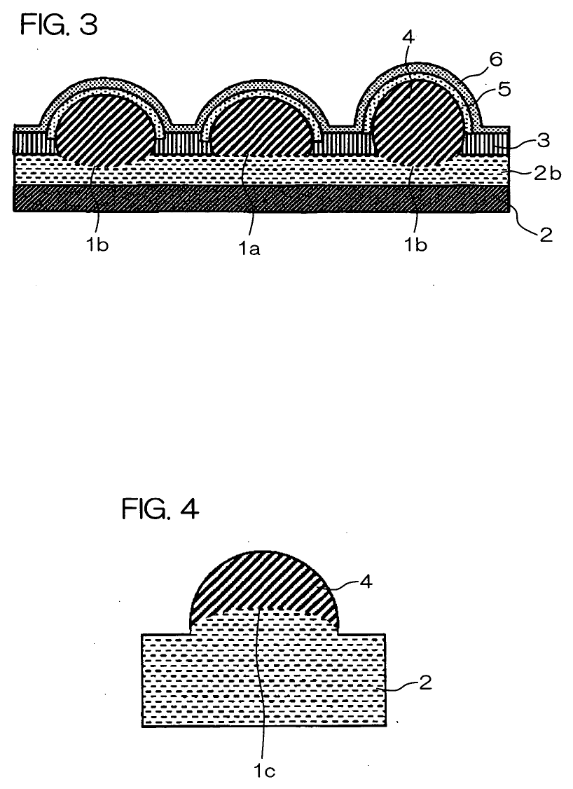

Actually in the conductive substrate 2 shown in FIG. 1, a contact between the conductive substrate 2 and the p-type crystal semiconductor particle 4 is heated and melted, so that an alloy layer (indicated by 2b in FIG. 3) containing a component of the conductive substrate 2 and a component of the p-type crystal semiconductor particle 4 is formed. The alloy layer composes a part of the conductive substrate 2.

When the conductive substrate 2 is composed of the composite material containing the aluminum alloy layer 2a mainly composed of aluminum and silicon and containing boron, as shown in FIG. 2, the quality of the underlying conductive substrate may be a metal or ceramics having a melting point that is not less than the melting point of aluminum. For example, simple metals such as iron (Fe) and nickel (Ni), low-thermal expansion alloys such as stainless steel (SUS), an Fe—Ni alloy, and an Fe—Ni—Co alloy, and ceramics such as an aluminum oxide (Al₂O₃) calcined body are used.

It is preferable that the thickness of the aluminum alloy layer 2a serving as a surface layer in the composite material is not less than 0.01 mm (10 μm) by uniformly joining a large number of p-type crystal semiconductor particles 4 onto the conductive substrate 2 as well as considering an amount of aluminum required to diffuse aluminum into the junction.

An intermediate layer (not shown) can be also provided as a barrier layer for controlling the production of the aluminum alloy layer 2a in the boundary between the aluminum alloy layer 2a and the conductive substrate 2 in the composite material. Usable as such an intermediate layer is nickel (Ni) or the like, for example. It is preferable that the thickness of the intermediate layer is not less than 0.001 mm (1 μm).

When the conductive substrate 2 is composed of the composite material, an aluminum layer can be also formed on a part or the whole of a surface on the opposite side of a surface on which the p-type crystal semiconductor particle 4 is disposed for the purpose of restraining warping of the conductive substrate 2 caused by a thermal load or the like.

It is preferable that the thickness of the conductive substrate 2 shown in FIGS. 1 and 2 is 0.1 to 2 mm. When the thickness is less than 0.1 mm, the conductive substrate 2 easily warps when the p-type crystal semiconductor particle 4 is welded to the conductive substrate 2 because the thickness of the conductive substrate 2 is reduced, thereby reducing the photoelectric conversion efficiency of the photoelectric conversion device. When the thickness exceeds 2 mm, the weight of the conductive substrate 2 itself is increased, thereby making it difficult to make the photoelectric conversion device lightweight.

According to the configuration of the present invention, boron is contained in the conductive substrate 2 or the aluminum alloy layer 2a on its surface. When the p-type crystal semiconductor particle 4 is heated and welded to the conductive substrate 2, therefore, boron in the conductive substrate 2 or the aluminum alloy layer 2a is diffused into the p-type crystal semiconductor particle 4. As a result, a p+ layer based on a ternary system of aluminum, boron, and silicon is formed in a portion, on the side of the conductive substrate 2 (lower electrode), of the p-type crystal semiconductor particle 4, and the p+ layer serves to further improve collection efficiency of minority carriers, thereby improving the photoelectric conversion efficiency.

The insulator 3 is composed of an insulating material for electrically separating and insulating a positive electrode and a negative electrode. The insulator 3 is composed of glass containing silicon oxide (SiO₂), aluminum oxide (Al₂O₃), lead oxide (PbO), boron oxide (B₂O₃), zinc oxide (ZnO), or the like as a component, a heat-resistant polymeric material, a mixture of a heat-resistant polymeric material and an inorganic filler, an organic/inorganic composite material containing silicon, a mixture of an organic/inorganic composite material containing silicon and an inorganic filler, an organic material, or the like.

The insulator 3 is formed on the surface of the conductive substrate 2 so as to be interposed between the p-type crystal semiconductor particles 4. The suitable thickness is preferably not less than 0.001 mm (1 μm) in a case where the insulator 3 is composed of a heat-resistant polymeric material, although it differs depending on the insulation resistance of the insulator 3.

The p-type crystal semiconductor particle 4 has boron, aluminum, gallium (Ga), etc. serving as p-type impurities as small amounts of elements contained in silicon. It is desirable that the particle diameter of the p-type crystal semiconductor particle 4 is 0.1 to 0.6 mm. When the particle diameter exceeds 0.6 mm, the used amount of silicon is the same as that in a conventional crystal plate system photoelectric conversion element, so that a merit in restraining the used amount of silicon using the p-type crystal semiconductor particle 4 is reduced. On the other hand, when the particle diameter is less than 0.1 mm, the loss of light energy is increased because light that is transmitted by the p-type crystal semiconductor particle 4 without being absorbed therein, so that the photoelectric conversion efficiency is liable to be reduced. The shape of the p-type crystal semiconductor particles 4 may be various shapes such as a spherical shape, a spheroidal shape, a polygonal cubic shape, and a shape obtained by rounding a corner of the polygonal cubic shape.

The n-type semiconductor layer 5 is composed of silicon (Si), for example, and is formed by introducing a small amount of a gas phase of a phosphorous compound or the like serving as n-type impurities into a gas phase of a silane compound, for example, using thermal diffusion, gas phase growth, or the line. The thickness of the n-type semiconductor layer 5 is preferably not less than 10 nm. The film quality may be any one of a crystalline substance, an amorphous substance, or a mixture of a crystalline substance and an amorphous substance. Considering light transmittance, however, a crystalline substance or a mixture of a crystalline substance and an amorphous substance is preferable.

Furthermore, it is preferable that the n-type semiconductor layer 5 is formed along a surface shape of the p-type crystal semiconductor particle 4. Consequently, the p-type crystal semiconductor particle 4 has a convexly curved surface. The area of a pn junction formed between the p-type crystal semiconductor particle 4 and the n-type semiconductor layer 5 can be increased, so that electrons generated by photoelectric conversion in the p-type crystal semiconductor particle 4 can be efficiently collected.

The p-type crystal semiconductor particle 4 having a region containing small amounts of phosphorous (P), arsenic (As), etc. serving as n-type impurities formed in a layered shape on its surface portion can be also used. In this case, the layered region is taken as the n-type semiconductor layer 5. The translucent conductive layer 6 is directly formed thereon.

The translucent conductive layer 6 is formed by a thin film forming method such as sputtering or gas phase growth, a coating and calcining method, or the like, and is formed by a film composed of one type of oxide or a plurality types of oxides selected out of tin oxide (SnO₂), indium oxide (In₂O₃), zinc oxide (ZnO), titanium oxide (TiO₂), ITO (Indium Tin Oxide), and so on or a film composed of one type of metal or a plurality of types of metals selected out of titanium (Ti), platinum (Pt), and gold (Au).

The translucent conductive layer 6 is transparent, and transmits a part of light incident on a portion where the p-type crystal semiconductor particle 4 does not exist and reflects the light on the conductive substrate 2 on the lower side to irradiate the light onto the p-type crystal semiconductor particles 4, thereby allowing light energy irradiated onto the whole photoelectric conversion device to be efficiently irradiated onto the p-type crystal semiconductor particle 4.

A protective layer (not shown) may be formed both on the conductive substrate 2 and on the lower part of p-type crystal semiconductor particles 4. Used as such a protective layer may be one having translucent and dielectric properties. For example, silicon oxide (SiO₂), cesium oxide (Ce₂O), aluminum oxide (Al₂O₃), silicon nitride (Si₃N₄), titanium oxide (TiO₂), tantalum oxide (Ta₂O₅), yttrium oxide (Y₂O₃), etc. may be formed by CVD (Chemical Vapor Deposition), PVD (Physical Vapor Deposition), or the like in a single composition or a plurality of compositions and in a single layer or a combination of a plurality of layers. The protective layer requires translucency because it is arranged on an incidence surface of light, and must be a dielectric member in order to prevent leakage of a current obtained by photoelectric conversion. Further, the protective layer can be expected to have the function of a reflection preventing film by optimizing the thickness thereof.

When the photoelectric conversion device is used as a solar cell, it is preferable that a pattern electrode (not shown) composed of finger electrodes and bus-bar electrodes with predetermined spacing is provided on the translucent conductive layer 6, to improve the conversion efficiency of photoelectric conversion.

In a case where the p-type crystal semiconductor particle 4 is then welded to the conductive substrate 2, the shape of the boundary surface 1 formed in the boundary of its junction and the p-type crystal semiconductor particle 4 is illustrated in FIG. 3.

FIG. 3 is a cross-sectional view of the solar cell, where a contact between the conductive substrate 2 and the p-type crystal semiconductor particle 4 is heated and melted, so that an alloy layer 2b containing a component of the conductive substrate 2 and a component of the p-type crystal semiconductor particle 4 is formed.

In FIG. 3, reference numeral 1a denotes a shape of a boundary surface in a case where a junction of the p-type crystal semiconductor particle 4 and the alloy layer 2b is substantially parallel to one main surface of the conductive substrate 2. Reference numeral 1b denotes a shape of a boundary surface whose center is more greatly projected toward the conductive substrate 2 than the outer periphery thereof.

The shapes of the boundary surfaces 1a and 1b can be realized by such a manufacturing method that when the p-type crystal semiocnductor particle 4 is joined to the conductive substrate 2, they are heated to not less than an eutectic point of their components (e.g., aluminum and silicon) to form an alloy layer 2b serving as an eutectic portion having viscosity, and pressure is applied such that the p-type crystal semiconductor particle 4 sinks into the alloy layer 2b. The horizontal shape of the boundary surface 1a or a convex shape under the boundary surface 1b can be obtained by adding or subtracting the pressure.

Initiation and development of cracks on the boundary surfaces 1a and 1b are restrained in reliability evaluation such as a temperature cycle by the shapes of the boundary surfaces 1a and 1b, thereby making it possible to obtain a photoelectric conversion device having high reliability whose photoelectric conversion efficiency is hardly degraded in actual use for a long time period.

For example, each of approximately 700 p-type crystal semiconductor particles 4 can have a downwardly convex shape, for example, the boundary surface 1b by applying pressure of about 0.002 to 1 N/cm² thereto from above. When the pressure is more than 0 and less than 0.002 N/cm², it is difficult to force each of the p-type crystal semiconductor particles 4 into the eutectic portion, so that the p-type crystal semiconductor particle 4 has a horizontal boundary surface, for example, the boundary surface 1a. When the pressure exceeds 1 N/cm², each of the p-type crystal semiconductor particles 4 is damaged, and the eutectic portion is too much pressed, so that an eutectic metal is easily extruded outward from a lower part of the p-type crystal semiconductor particle 4.

When the p-type crystal semiconductor particle 4 is joined only by eutectic formation without being pressurized, the progress of an eutectic crystal in a natural oxide film formed on the surface of the p-type crystal semiconductor particle 4 is slower than the progress of an eutectic crystal inside the p-type crystal semiconductor particle 4, so that the p-type crystal semiconductor particle has such a shape that the outer periphery thereof is positioned closer to the conductive substrate 2 than the center of a boundary surface 1c, as shown in FIG. 4.

In the present invention, the p-type crystal semiconductor particle 4 is pressurized toward the conductive substrate 2 at the time of eutectic formation in the junction, so that the outer periphery of the p-type crystal semiconductor particle 4 that is positioned on the side of the conductive substrate 2 is pressed into the eutectic crystal so that eutectic formation in the outer periphery is promoted.

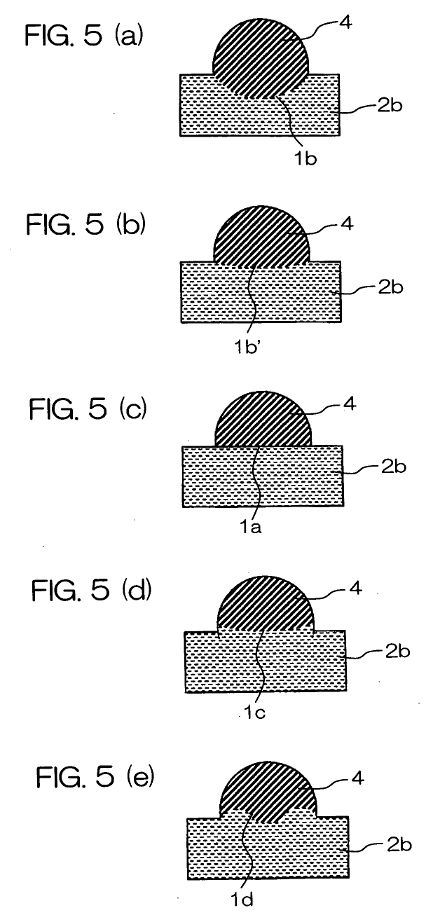

As a result, the boundary surface is substantially parallel to one main surface of the conductive substrate 2, as shown in FIG. 5(c), or the center of the boundary surface is positioned closer to the conductive substrate 2 than the outer periphery, as shown in FIGS. 5(a), 5(b), 5(c), 5(d) and 5(e).

Description is now made of the steps of a method of manufacturing the photoelectric conversion device according to the present invention.

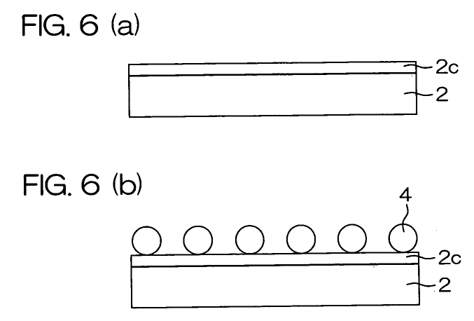

First, at least one type selected from a group consisting of boron powder, an inorganic boron compound, and an organic boron compound is applied on a surface of a conductive substrate 2 having an aluminum layer containing no boron formed on its surface, that is, on the surface of the aluminum layer, to form a boron compound layer 2c containing boron of 0.1×10⁻⁵ to 1×10⁻⁵ g/cm² in boron terms, as shown in FIG. 6(a).

The inorganic boron compound is composed of at least one type selected from a group consisting of carbide, oxide (fluoboric acid), chloride, bromide, iodide, fluoride, and nitride. Particularly, the inorganic boron compound is preferably composed of at least one type selected out of carbide, oxide, and chloride. In this case, a chemically stable boron compound layer 2c can be formed. When a p-type crystal semiconductor particle 4 is joined to the conductive substrate 2 by heating and welding, boron can be stably diffused and doped into its junction.

The organic boron compound may be composed of at least one type selected from a group consisting of trimethoxyboron, triethoxyboron, tripropoxyboron, and tributoxyboron. In this case, the organic boron compound such as trimethoxyboron can be easily formed by being applied or sprayed with the organic boron compound contained in alcohol, water, or the like.

The boron compound layer 2c is formed by melting boron powder, an inorganic boron compound, or an organic boron compound, for example, in alcohol, water, or the like, to prepare a solution, and applying the solution using a spin coat or the like, followed by drying.

Although description was made of an example in which the boron compound layer 2c is formed on the surface of the aluminum layer by coating, an aluminum substrate containing boron may be used, as shown in FIG. 1, as the conductive substrate 2. A substrate composed of a composite material containing an aluminum alloy layer 2a may be used, as shown in FIG. 2.

A plurality of p-type crystal semiconductor particles 4 are arranged on the boron compound layer 2c, and are heated at 560 to 660° C. for one to twenty minutes, to weld each of the p-type crystal semiconductor particles 4 to the conductive substrate 2, as shown in FIG. 6(b). Consequently, an alloy layer (an eutectic portion) mainly composed of aluminum and silicon is formed in the junction serving as a welded portion. At the time of the welding, aluminum in the conductive substrate 2 and boron in the boron compound layer 2c are diffused into the p-type crystal semiconductor particle 4, and are distributed such that aluminum and boron are contained in large amounts on the side of the conductive substrate 2 within the p-type crystal semiconductor particle 4. Thus, a p+ layer is formed on the side of the conductive substrate 2 (lower electrode) in the p-type crystal semiconductor particle 4, and the p+ layer serves to improve the collection efficiency of p-type carriers, thereby improving photoelectric conversion efficiency.

As described in the foregoing, it is preferable that a heating temperature in welding the p-type crystal semiconductor particle 4 to the conductive substrate 2 is 560 to 660° C. When the heating temperature is less than 560° C., formation reaction of an alloy of aluminum and boron does not occur, so that the p-type crystal semiconductor particle 4 is not easily welded. When the heating temperature exceeds 660° C., it is not less than the melting point of aluminum, so that the conductive substrate 2 does not fulfil its original funciton because it is melted and deformed, for example.

Thereafter, the step of joining a partial region of each of the plurality of p-type crystal semiconductor particles 4 onto the conductive substrate 2 having the boron compound layer 2c formed on its surface by heating and welding as well as diffusing boron in the boron compound layer 2c into its junction is carried out.

After the step is carried out, the step of forming an n-type semiconductor portion (an n-type semiconductor layer 5), except for the junction, on the surface of the p-type crystal semiconductor particle 4, the step of covering a lower part of the n-type semiconductor portion and the conductive substrate 2 between the adjacent p-type semiconductor particles 4 and forming an insulator 3 with an upper part of the n-type semiconductor portion exposed, and the step of forming a translucent conductive layer 6 for covering the insulator 3 and an upper part of the n-type semiconductor portion are successively carried out.

In a case where the insulator 3 is composed of a sufficiently heat-resistant material, the step of forming the n-type semiconductor portion on the surface of the p-type crystal semiconductor particle 4 may be carried out after the insulator 3 is formed.

The photoelectric conversion device according to the present invention can be also manufactured by the following steps.

That is, the step of forming an n-type semiconductor portion on the entire surface of a plurality of p-type crystal semiconductor particles 4 by thermal diffusion is carried out.

Thereafter, the step of joining a partial region of each of the plurality of p-type crystal semiconductor particles 4 on a conductive substrate 2 having a boron compound layer 2c formed on its surface by heating and welding as well as diffusing boron in the boron compound layer 2c into its junction, the step of covering a lower part of the n-type semiconductor portion and the conductive substrate 2 between the adjacent p-type semiconductor particles 4 and forming an insulator 3 with an upper part of the n-type semiconductor portion exposed, and the step of forming a translucent conductive layer 6 covering the insulator 3 and the upper part of the n-type semiconductor portion are successively carried out.

Although the present invention has been described and illustrated in detail, it is clearly understood that the same is by way of illustration and example only and is not to be taken by way of limitation, the spirit and scope of the present invention being limited only by the terms of the appended claims.

### EXAMPLE

Since the photoelectric conversion device according to the present invention is manufactured, a method of manufacturing the same will be specifically described.

### Example 1

A conductive substrate 2 of aluminum quality whose boron content is changed into various values was degreased using a sodium hydroxide (NaOH) solution and was then neutralized using a nitric acid (HNO₃) solution, to clean its surface. A plurality of p-type crystal semiconductor particles 4 composed of p-type silicon particles having a diameter of about 0.5 mm from which a surface oxide layer was removed using a hydrofluoric acid (HF) solution were arranged on the conductive substrate 2, and were heated at 600 to 630° C. for one to ten minutes, to diffuse and join a lower part of each of the p-type crystal semiconductor particles 4 into and to the conductive substrate 2.

Polyimide was then used as an insulator 3, was applied so as to have a thickness of about 100 μm between the p-type crystal semiconductor particles 4, was dried at 200° C. for thirty minutes, and was then calcined at 350° C. for one hour, to form the layered insulator 3.

An n-type semiconductor layer 5 composed of an n-type silicon layer consisting of a mixed crystal of a crystalline substance and an amorphous substance was deposited to a thickness of about 15 nm on the p-type silicon particles and the insulator 3, and an ITO layer (a translucent conductive layer) having a thickness of 85 nm was further formed thereon by sputtering, to manufacture seven types of photoelectric conversion devices that differ in boron concentration in the conductive substrate 2.

With respect to the photoelectric conversion devices, the results of measuring photoelectric conversion efficiency under conditions of AM (Air Mass) 1.5 using a solar simulator are shown in Table 1.

TABLE 1

| | | Boron | Boron | |
|---|---|---|---|---|
| | | concentration | concen- | |
| | Boron | in area other | traiton | |
| | content in | than junction | in junction | |
| | conductive | of silicon | of silicon | Photoelectroc |
| Sample | substrate | particle | particle | conversion |
| No. | (ppm) | (ppm) | (ppm) | efficiency (%) |
| 1 | 0 | 0.2 | 0.2 | 9.1 |
| 2 | 50 | 0.2 | 30 | 10.8 |
| 3 | 180 | 0.2 | 100 | 11.3 |
| 4 | 220 | 0.2 | 140 | 11.9 |
| 5 | 300 | 0.2 | 200 | 11.6 |
| 6 | 500 | 0.2 | — | Abondon change |
| | | | | into cell |
| | | | | because aluminum |
| | | | | boride is |
| | | | | deposited in |
| | | | | conductive |
| | | | | substrate |
| 7 | 20000 | 0.2 | — | Abondon change |
| | | | | into cell |
| | | | | because aluminum |
| | | | | boride is |
| | | | | deposited in |
| | | | | conductive |
| | | | | substrate |

From Table 1, high photoelectric conversion efficiency was obtained with respect to the photoelectric conversion devices (samples No. 2 to 5) in which boron was contained in the conductive substrate 2. With respect to p-type silicon particles in the photoelectric conversion devices (samples No. 2 to 5) in which high photoelectric conversion efficiency was obtained, when a boron concentration inside thereof was analyzed by SIMS (Secondary Ion Mass Spectroscopy), it was confirmed that boron and aluminum were diffused into a junction of the p-type crystal semiconductor particle 4 with the conductive substrate 2, so that it was confirmed that a BSF effect was improved.

On the other hand, with respect to the photoelectric conversion device (sample No. 1) in which no boron was contained in the conductive substrate 2, photoelectric conversion efficiency was low, and diffusion of boron and aluminum could not be confirmed even by SIMS analysis inside the p-type silicon particles, so that it was confirmed that a BSF effect was not obtained.

It was found that the amount of boron contained in junction in each of the samples No. 2 to 5 in which there was a BSF effect produced by a p+ layer was preferably at least not less than 150 times the amount of boron originally contained in the silicon particles.

With respect to the photoelectric conversion devices (samples No. 6 and 7) in which a boron concentration in the conductive substrate 2 was more than 300 ppm, boron that is not less than an eutectic composition was deposited as aluminum boride (AlBₓ) into the conductive substrate 2, so that the conductive substrate 2 that is uniform in composition could not be produced. Therefore, a change into photoelectric conversion elements (cells) was abandoned.

The photoelectric conversion device (sample No. 2) in which a boron concentraiton in the conductive substrate 2 was not more than 50 ppm, the BFS effect in the present invention was lowered.

### Example 2

A boric acid solution whose boron concentration is changed into various values was applied to a conductive substrate 2 of aluminum quality whose surface was cleaned by being degreased using a sodium hydroxide solution and then neutralized using a nitric acid solution, followed by drying, to produce conductive substrates 2 respectively having boron compound layers 2c that differ in amount of boron per unit area. A plurality of p-type silicon particles having a diameter of about 0.5 mm from which a surface oxide layer was removed using a hydrofluoric acid solution were arranged on the boron compound layer 2c, and were heated at 600 to 630° C. for one to ten minutes, to diffuse and join a lower part of each of the p-type silicon particles into and to the conductive substrate 2.

Polyimide was then used as an insulator 3, was applied so as to have a thickness of about 100 μm between the p-type silicon particles, was dried at 200° C. for thirty minutes, and was then calcined at 350° C. for one hour, to form the layered insulator 3.

An n-type silicon layer composed of a mixed crystal of a crystalline substance and an amorphous substance was deposited to a thickness of about 15 nm on the p-type silicon particles and the insulator 3 by plasma CVD using mixed gas composed of silane gas and a small amount of a phosphor compound, and an ITO layer (a translucent conductive layer) having a thickness of 85 nm was further formed thereon by sputtering, to manufacture seven types of photoelectric conversion devices that differ in boron concentration in the boron compound layer 2c. With respect to the photoelectric conversion devices, the results of measuring photoelectric conversion efficiency under conditions of AM 1.5 using a solar simulator are shown in Table 2.

TABLE 2

| | | Boron | | |
|---|---|---|---|---|
| | Boron | concentration | Boron | |
| | amount in | in area other | concentration | |
| | boron | than junction | in junction of | Photoelectric |
| | compound | of silicon | silicon | conversion |
| Sample | layer | particle | particle | efficiency |
| No. | (×10⁻⁵ g/cm²) | (ppm) | (ppm) | (%) |
| 1 | 0 | 0.2 | 0.2 | 8.4 |
| 2 | 0.05 | 0.2 | 10 | 9.3 |
| 3 | 0.1 | 0.2 | 30 | 10.6 |
| 4 | 0.4 | 0.2 | 100 | 11.9 |
| 5 | 0.7 | 0.2 | 160 | 13.1 |
| 6 | 1.0 | 0.2 | 200 | 11.1 |
| 7 | 1.3 | 0.2 | 250 | 9.0 |

From Table 2, high photoelectric conversion efficiency was obtained by forming the boron compound layers 2c (samples No. 3 to 6) containing boron of 0.1×10⁻⁵ to 1×10⁻⁵ g/cm² in boron terms. With respect to the p-type silicon particles in the photoelectric conversion device in which high photoelectric conversion efficiency was obtained, when a boron concentration inside thereof was confirmed by SIMS analysis, it was confirmed that the p-type silicon particles were distributed at high concentration on the side of the conductive substrate 2.

It was found that the amount of boron contained in each of the junctions in the samples No. 2 to 7 in which there was a BSF effect produced by a p+ layer was preferably at least not less than 50 times the amunt of boron originally contained in the silicon particles.

### Example 3

A surface of each of p-type crystal semiconductor particles 4 having an average particle diameter of 400 μm to which a small amount of boron (B) was added as a p-type dopant was washed, followed by thermal diffusion at 850° C. for thirty minutes in a POCl₃ atmosphere, to form an n-type silicon layer as an n-type semiconductor layer 5 on the surface of the p-type crystal semiconductor particle 4. At this time, a portion into which boron is not diffused was covered with silicon oxide, to form an n-type silicon layer in only a necessary portion.

One layer of p-type crystal semiconductor particles 4 each having an n-type silicon layer formed therein was then densely disposed on the conductive substrate 2 made of aluminum, to change diffusion and junction conditions such as junction temperature, junction time, temperature rise speed, and temperature fall speed in various ways, thereby producing samples in which the conductive substrate 2 and the p-type crystal semiconductor particles 4 were diffused and joined to each other.

Polyimide was then selected as an insulator material for an insulator 3, to form the insulator 3 so as to cover a surface of the conductive substrate 2 between the p-type crystal semiconductor particles 4. A translucent conductor layer 6 composed of ITO was then formed to a thickness of 100 nm on the conductive substrate 2, to manufacture a photoelectric conversion device.

The results of carrying out initial photoelectric conversion characteristics, reliability evaluation, and cross-section observation of the photoelectric conversion device to confirm the presence or absence of crack development and the shape of a boundary surface are shown in Table 3. Reliability was evaluated by conducting a temperature cycle test in 500 cycles with a temperature set to −40° C. to 90° C. and six hours taken as one cycle, to evaluate the reduction ratios of the photoelectric conversion efficiency before and after the reliability evaluation. The results are shown in Table 3.

TABLE 3

| | | | | Conversion | |
|---|---|---|---|---|---|
| | | | | efficiency | |
| | Shape of | Shape of | Initial | after | |
| | boundary | boundary | conversion | reliability | Change |
| Sample | surface | surface | efficiency | evaluation | ratio |
| 1 | Projected | FIG. 5 (a) | 12.6% | 12.3% | −2.4% |
| | toward | | | | |
| | substrate | | | | |
| 2 | Projected | FIG. 5 (b) | 11.8% | 11.6% | −1.7% |
| | toward | | | | |
| | substrate | | | | |
| 3 | Parallel | FIG. 5 (c) | 11.9% | 11.6% | −2.6% |
| | to | | | | |
| | substrate | | | | |
| 4 | Parallel | FIG. 5 (c) | 11.3% | 11.1% | −1.8% |
| | to | | | | |
| | substrate | | | | |
| 5 | Projected | FIG. 5 (d) | 10.8% | 10.7% | −0.9% |
| | toward | | | | |
| | substrate | | | | |
| 6 | Center is | FIG. 5 (e) | 11.2% | 10.9% | −2.7% |
| | projected | | | | |
| | toward | | | | |
| | substrate | | | | |
| 7* | Projected | | 8.6% | 8.1% | −5.9% |
| | toward | | | | |
| | silicon | | | | |
| | particle | | | | |
| 8* | Projected | | 9.2% | 8.7% | −5.4% |
| | toward | | | | |
| | silicon | | | | |
| | particle | | | | |

In Table 3, the sample 1 is an example in which a pressure of 0.07 N/cm² was applied to 700 p-type crystal semiconductor particles 4 to join the p-type crystal semiconductor particle 4 to the conductive substrate 2, the sample 2 is an example in which a pressure of 0.06 N/cm² was applied to 700 p-type crystal semiconductor particles 4, the sample 3 is an example in which a pressure of 0.05 N/cm² was applied to 700 p-type crystal semiconductor particles 4, the sample 4 is an example in which a pressure of 0.04 N/cm was applied to 700 p-type crystal semiconductor particles 4, the sample 5 is an example in which a pressure of 0.03 N/cm² was applied to 700 p-type crystal semiconductor particles 4, and the sample 6 is an example in which a pressure of 0.02 N/cm² was applied to 700 p-type crystal semiconductor particles 4.

The samples 7 and 8 are examples in which no pressure was applied to p-type crystal semiconductor particle 4 when they were joined to the conductive substrate 2.

It was found from the results shown in Table 3 that crack development after reliability evaluation was not confirmed so that a photoelectric conversion efficiency degradation ratio was also reduced depending on whether a boundary surface between an alloy layer (a junction) formed by heating and welding the conductive substrate 2 and the p-type crystal semiconductor particle 4 and the remainder of the p-type crystal semiconductor particle 4 is substantially parallel to one main surface of the conductive substrate 2 or whether or not the center of the boundary surface is positioned closer to the conductive substrate 2 than the outer periphery thereof.

The present application corresponds to Japanese Patent Application No. 2004-332931 filed with the Japanese Patent Office on Nov. 17, 2004 and Japanese Patent Application No. 2004-348403 filed with the Japanese Patent Office on Dec. 1, 2004, the disclosures of which are incorporated herein by reference.

What is claimed is:

1. A photoelectric conversion device, comprising
a conductive substrate;
a plurality of p-type crystal semiconductor particles joined to one main surface of the conductive substrate;
an insulator interposed between the adjacent p-type crystal semiconductor particles on the one main surface of the conductive substrate; and
a n-type semiconductor layer and a translucent conductor layer that are formed on a portion, exposed from the insulator, of each of the p-type crystal semiconductor particles, wherein a boron concentration in a junction of the p-type crystal semiconductor particle with the conductive substrate is higher than a boron concentration in a portion, other than the junction, of the p-type crystal semiconductor particle.

2. The photoelectric conversion device according to claim 1, wherein
the conductive substrate is composed of aluminum containing boron.

3. The photoelectric conversion device according to claim 2, wherein
the content of boron in the conductive substrate is 50 to 300 ppm.

4. The photoelectric conversion device according to claim 1, wherein
the conductive substrate has an aluminum layer containing boron formed on its surface.

5. The photoelectric conversion device according to claim 4, wherein
the content of boron in the aluminum layer is 50 to 300 ppm.

6. The photoelectric conversion device according to claim 4, wherein
the thickness of the aluminum layer is not less than 10 μm.

7. The photoelectric conversion device according to claim 4, wherein
the conductive substrate is composed of aluminum, a metal having a melting point that is not less than the melting point of aluminum, or ceramics.

8. A method of manufacturing a photoelectric conversion device, comprising the steps of:
(a) preparing a plurality of p-type crystal semiconductor particles as well as preparing a conductive substrate containing boron;
(b) joining each of the plurality of p-type crystal semiconductor particles onto the conductive substrate by heating and welding, to diffuse boron into its junction;
(c) first carrying out either one of (c1) the step of forming an n-type semiconductor portion except for at least the junction on a surface of each of the p-type crystal semiconductor particles, and (c2) the step of covering a lower part of the n-type semiconductor portion and the conductive substrate between the adjacent p-type crystal semiconductor particles and exposing an upper part of the n-type semiconductor portion to form an insulator, and then carrying out the other step; and
(d) forming a translucent conductive layer that covers the insulator and the upper part of the n-type semiconductor portion.

9. The method according to claim 8, wherein
the conductive substrate containing boron is a conductive substrate having a boron compound layer formed on its surface.

10. The method according to claim 8, wherein
the conductive substrate containing boron is either one of a conductive substrate containing boron and a conductive substrate having a layer containing boron formed on its surface.

11. The method according to claim 9, wherein
the boron compound layer is composed of at least one type of inorganic boron compound selected out of carbide, oxide, and chloride.

12. The method according to claim 9, wherein
the boron compound layer is composed of at least one type of organic boron compound selected out of trimethoxyboron, triethoxyboron, tripropoxyboron, and tributoxyboron.

13. The method according to claim 9, wherein
the content of boron in the boron compound layer is 0.1×10⁻⁵ to 1×10⁻⁵ g/cm³.

14. The method according to claim 8, wherein
the conductive substrate is aluminum, and heating temperature in carrying out the step (b) is 560 to 660° C.

15. A method of manufacturing a photoelectric conversion device, comprising the steps of:
(e) preparing a plurality of p-type crystal semiconductor particles as well as preparing a conductive substrate containing boron;
(f) forming an n-type semiconductor portion on the entire surface of each of the plurality of p-type crystal semiconductor particles by thermal diffusion;
(g) joining each of the plurality of p-type crystal semiconductor particles onto the conductive substrate by heating and welding, to diffuse boron into its junction;
(h) covering a lower part of the n-type semiconductor portion and the conductive substrate between the adjacent p-type crystal semiconductor particles and exposing an upper part of the n-type semiconductor portion, to form an insulator; and
(i) forming a translucent conductive layer that covers the insulator and the upper part of the n-type semiconductor portion.

16. The method according to claim 15, wherein
the conductive substrate containing boron is a conductive substrate having a boron compound layer formed on its surface.

17. The method according to claim 15, wherein
the conductive substrate containing boron is either one of a conductive substrate containing boron and a conductive substrate having a layer containing boron formed on its surface.

18. The method according to claim 16, wherein
the boron compound layer is composed of at least one type of inorganic boron compound selected out of carbide, oxide, and chloride.

19. The method according to claim 16, wherein
the boron compound layer is composed of at least one type of organic boron compound selected out of trimethoxyboron, triethoxyboron, tripropoxyboron, and tributoxyboron.

20. The method according to claim 16, wherein
the content of boron in the boron compound layer is 0.1×10⁻⁵ to 1×10⁻⁵ g/cm³.

21. The method according to claim 15, wherein
the conductive substrate is aluminum, and heating temperature in carrying out the step (f) is 560 to 660° C.

22. A photoelectric apparatus using the photoelectric conversion device according to claim 1 as power generation means and configured so as to supply power generated by the power generation means to a load.
